(19) United States
(12) Patent Application Publication
(10) Pub. No.: US 2026/0367532 A1
(43) Pub. Date: Nov. 19, 2026

(54) METROLOGY METHOD AND ASSOCIATED METROLOGY DEVICE

(71) Applicant: ASML Netherlands B.V., Veldhoven (NL)

(72) Inventors: Mustafa Ümit ARABUL, Eindhoven (NL); Zili ZHOU, Veldhoven (NL); Nitesh PANDEY, Santa Clara, CA (US); Coen Adrianus VERSCHUREN, Eindhoven (NL); Willem Marie Julia Marcel COENE, Mierlo (NL); Gerard Jan VERBIEST, Chaam (NL); Peter Gerard STEENEKEN, Delfgauw (NL)

(73) Assignee: ASML Netherlands B.V., Veldhoven (NL)

(21) Appl. No.: 19/155,297

(22) PCT Filed: Jan. 17, 2024
(86) PCT No.: PCT/EP2024/051020

§ 371 Date: Aug. 11, 2025

Related U.S. Application Data
(60) Provisional application No. 63/445,412, filed on Feb. 14, 2023.

(51) Int. Cl. G03F 7/00; G01B 17/00

(52) U.S. Cl. CPC G03F 7/70683; G01B 17/00; G03F 7/70633; G03F 7/70655; G03F 7/706851

(57) ABSTRACT

Disclosed is a substrate comprising at least one target, said target comprising: a reference sub-structure in a top layer; and a buried sub-structure in a buried layer below the top layer. The buried sub-structure comprises a non-constant pitch in at least one direction, such as a zone-plate, the effect of the non-constant pitch being that reflected waves, reflected from the sub-structure as a result of a measurement of said target, are at least partially focused towards a focus point.

### CROSS-REFERENCE TO RELATED APPLICATIONS

This application claims priority of U.S. application 63/445,412 which was filed on 14 Feb. 2023 and which is incorporated herein in its entirety by reference.

### FIELD

The present invention relates to a metrology method and device which may, for example, be used for determining a characteristic of structures on a substrate.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

In lithographic processes, it is desirable to make frequently measurements of the structures created, e.g., for process control and verification. Various tools for making such measurements are known, including scanning electron microscopes or various forms of metrology apparatuses, such as scatterometers. A general term to refer to such tools may be metrology apparatuses or inspection apparatuses.

Metrology tools are known that can measure overlay in target structures having pitches down to around 10 nm if the separation between the overlying layers (e.g. gratings formed in different layers) is of a similar order of size. Metrology tools are also known that can measure overlay between overlying layers that are spaced further apart, but only if the pitch of the target structures is also commensurately larger. It has been difficult to measure overlay in target structures having relatively small pitch (e.g. around 10 nm) and relatively large separation between the overlying layers (e.g. greater than 100 nm). A further challenge is the increasing use of material layers that are not transparent to visible light, such as metal or carbon layers, or chalcogenide materials used for example in 3D memory applications. Portions of target structures below such opaque layers may not be accessible to many existing metrology techniques based on scatterometry.

A particular metrology technique, referred to herein as photoacoustic sub-surface atomic force microscopy (passAFM), and an associated metrology apparatus is described in WO2021028174A1, which is incorporated herein by reference. This technique was devised to address one or more of the issues highlighted in the previous paragraph.

In the passAFM technique, an AFM cantilever is used as a very high frequency ultrasound transducer (e.g., at a frequency of about 100 GHz). This transducer is actuated via an optical pump pulse on the cantilever. The generated acoustic waves enter the sample via the cantilever tip, and reflected echoes are detected when they arrive back at the cantilever surface via an optical probe beam (e.g., displacement or reflectivity).

It is desirable to improve methods of performing such photoacoustic sub-surface atomic force microscopy.

### SUMMARY

Embodiments of the invention are disclosed in the claims and in the detailed description.

In a first aspect of the invention there is provided a substrate comprising at least one target, said target comprising: a reference sub-structure in a top layer; and a buried sub-structure in a buried layer below the top layer, wherein said buried sub-structure comprises a non-constant pitch in at least one direction, the effect of the non-constant pitch being that reflected waves, reflected from the sub-structure as a result of a measurement of said target, are at least partially focused towards a focus point.

According to a second aspect of the present invention there is provided a method of measuring a parameter of interest value by measuring a target, the target comprising a reference sub-structure in a top layer; and a buried sub-structure in a buried layer below the top layer, wherein said buried sub-structure comprises a non-constant pitch in at least one direction, the effect of the non-constant pitch being that reflected waves, reflected from the sub-structure as a result of a measurement of said target, are at least partially focused towards a focus point; the method comprising: a) determining a position of the reference structure via an atomic force microscopy method; b) generating acoustic waves at the positon of the reference structure determined at step a) and directing said acoustic waves towards said buried sub-structure; c) measuring a strength metric value of a reflected wave at the positon of the reference structure determined at step a), having reflected from said buried sub-structure as a result of step b); and d) determining a parameter of interest value from the strength metric value.

The invention yet further provides a metrology device operable to perform the method of the second aspect.

These and other aspects and advantages of the apparatus and methods disclosed herein will be appreciated from a consideration of the following description and drawings of exemplary embodiments.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 is schematic side view of a metrology tool having a cantilever probe, an ultrasound generation system, and an ultrasound detection system;

FIG. 5 is a schematic side sectional view of a probe element in a transmit mode;

FIG. 6 is a schematic side sectional view of the probe element of FIG. 4 in a receive mode;

FIG. 7 is an illustration of (a) a probe element performing a measurement on a target according to a first embodiment, and (b) a probe element performing a measurement on a target according to a second embodiment;

FIGS. 8(a) and 8(b) comprises respectively an illustration of a sub-target comprising a first bias and a sub-target comprising a second bias according to embodiments;

FIGS. 9(a) and 9(b) comprises respectively an illustration of a first reference sub-structure layer according to an embodiment and a second reference sub-structure layer according to an embodiment; and

FIGS. 10(a), 10(b) and 10(c) comprises respectively an illustration of a first zone-plate sub-structure layer according to an embodiment, a second zone-plate sub-structure layer according to an embodiment and a third zone-plate sub-structure layer according to an embodiment.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

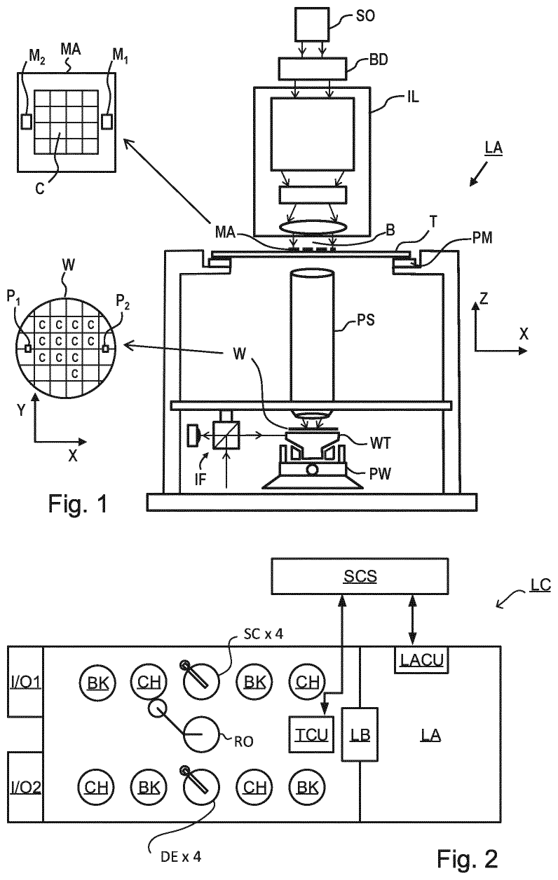

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

As shown in FIG. 2 the lithographic apparatus LA may form part of a lithographic cell LC, also sometimes referred to as a lithocell or (litho) cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

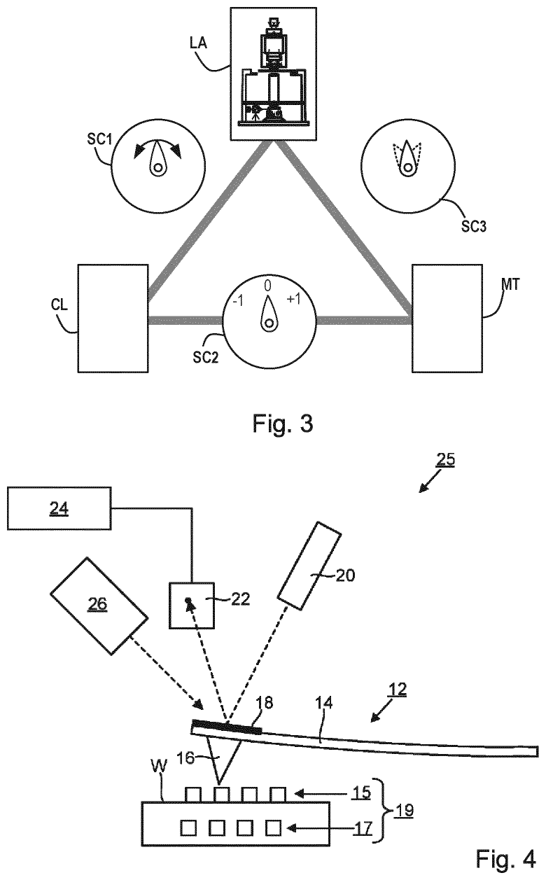

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MET (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)-typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MET) to predict whether defects may be present due to e.g. sub-optimal processing (depicted in FIG. 3 by the arrow pointing “0” in the second scale SC2).

The metrology tool MET may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

In lithographic processes, it is desirable to make frequently measurements of the structures created, e.g., for process control and verification. Various tools for making such measurements are known, including scanning electron microscopes or various forms of metrology apparatuses, such as scatterometers.

FIG. 4 is a schematic illustration of a metrology apparatus described in WO2021028174A1. The apparatus comprises a cantilever probe 12 configured to provide high spatial resolution information about features present below an outer surface of an entity to be investigated with minimal or no risk of damage to the entity. The cantilever probe 12 is provided as part of a measurement system 25. In some embodiments, examples of which are given below, the entity to be investigated is a target structure 19 formed on a substrate W using a lithographic process. In such embodiments, the measurement system 25 may be referred to as a metrology tool.

In an embodiment, the cantilever probe 12 comprises a cantilever arm 14 and a probe element 16. The probe element 16 extends from the cantilever arm 14 towards the target structure 19 on the substrate W (generally downwards in FIG. 4). In an embodiment, the cantilever arm 14 and probe element 16 are configured (e.g. via their material properties and dimensions) to be capable of performing the functions of the cantilever in a standard atomic force microscope. In an embodiment, either or both of the cantilever arm 14 and probe element 16 is/are formed from silicon.

In an embodiment, the measurement system 25 is configured to generate ultrasonic waves in the cantilever probe 12. The ultrasonic waves propagate through the probe element 16 and into the target structure 19. The ultrasonic waves are reflected back from the target structure 19 into the probe element 16 or into a further probe element 32 (described below) extending from the cantilever arm 14.

In an embodiment, the ultrasonic waves are generated in the cantilever probe 12 using the photoacoustic effect. In some embodiments of this type, the generation of the ultrasonic waves is performed by directing a laser beam onto the cantilever probe 12. In the example of FIG. 4, a laser beam is directed onto the cantilever probe 12 by a first laser unit 26. The first laser unit 26 may be considered as forming all or part of an ultrasound generation system.

The nature of the laser beam provided by the first laser unit 26 is not particularly limited as long as the required ultrasonic waves are generated. The laser beam may, for example, comprise a femtosecond laser. In one embodiment, a laser pulse of between 10 fs and 900 fs, or between 10 fs and 500 fs, between 100 fs and 500 fs, between 100 fs and 300 fs or approximately 200 fs may be used. The laser pulse may have a pulse energy of between 1 nJ and 10nj (e.g., approx. 6 nJ) for example. By way of a specific example, the pulse may comprise a peak power of 30 kW. The repetition rate of this pulse may be between 10 MHz and 100 MHz (e.g., approximately 50 MHz) and the average power between 100 mW and 1 W (e.g., on the order of 300 mW).

In an embodiment, as exemplified in FIG. 4, an ultrasound generation layer 18 is provided on the cantilever arm 14. The laser beam from the first laser unit 26 is directed onto the ultrasound generation layer 18 to generate ultrasonic waves in the ultrasound generation layer 18. In embodiments of this type, the combination of the first laser unit 26 and the ultrasound generation layer 18 may be considered as forming all or part of an ultrasound generation system. In an embodiment, the ultrasound generation layer 18 is configured to provide higher absorbance per unit area with respect to the laser beam from the first laser unit 26 than would the cantilever arm 14 in the absence of the ultrasound generation layer 18. It is also desirable for the photoacoustic conversion efficiency associated with the absorption to be high and stable. The ultrasound generation layer 18 desirably has both a high absorbance per unit area at the frequency of the laser beam from the first laser unit 20 and a thermal diffusion speed of the same order of magnitude as the laser pulse duration (e.g. of the order of femtoseconds) for high photoacoustic conversion efficiency. In an embodiment, the ultrasound generation layer 18 may comprise a metallic material, such as aluminium, gold or titanium. Alternatively or additionally, the ultrasound generation layer 18 may be arranged to comprise highly absorbing carbon-based materials, such as amorphous carbon. The ultrasound generation layer 18 may comprise a single layer having uniform composition through the thickness of the single layer. Alternatively, the ultrasound generation layer 18 may comprise a composite layer having multiple individual layers. In an embodiment, at least a subset of the individual layers have different compositions relative to each other. It is also desirable to arrange for efficient transmission of the generated ultrasonic waves, for example by avoiding excessive reflection at interfaces within the ultrasound generation layer 18 and/or between the ultrasound generation layer 18 and the cantilever arm 14. This can be achieved by reducing the size of acoustic impedance mismatches at the interfaces. In an embodiment, an impedance-matching layer is provided between the ultrasound generation layer 18 and the cantilever arm 14. The acoustic impedance of the impedance-matching layer is between an acoustic impedance of the ultrasound generation layer 18 and an acoustic impedance of the cantilever arm 14.

In an embodiment, the composition and dimensions of the ultrasound generation layer 18 are selected so that at least a portion of the ultrasonic waves generated in the ultrasound generation layer 18 have a frequency higher than 15 GHZ, optionally higher than 50 GHz, optionally higher than 100 GHz. Providing ultrasonic waves in the range of 15 GHz to 50 GHz provides sub-micron resolution of spatial features within the target structure 19. Providing ultrasonic waves having a frequency higher than 100 GHz (e.g. in the range of 100 GHz to 200 GHz) provide nanometer resolution of spatial features within the target structure 19. Providing ultrasonic waves in the intermediate range of 50 GHz to 100 GHz provides intermediate resolution of spatial features.

The thickness of the ultrasound generation layer 18 may influence the frequency of the generated ultrasound. When the thickness of the ultrasound generation layer 18 is comparable to or smaller than the skin depth (with respect to the laser beam from the first laser unit 26), the thickness t of the ultrasound generation layer 18 and the frequency f of the ultrasound may be related according to f=v/2t when v is the speed of sound in the ultrasound generation layer 18. If the thickness t is larger than the skin depth, the skin depth acts as a bottle neck. The skin depth is determined by the complex refractive index of the ultrasound generation layer 18.

Based on the above, forming the ultrasound generation layer 18 from a homogeneous layer of aluminium having a thickness of e.g., 30 nm, or a homogeneous layer of amorphous carbon having a thickness of 85 nm or less, would be suitable for generating ultrasonic waves have frequencies above 100 GHz. As explained above, the required thicknesses depend on the speed of sound in the ultrasound generation layer 18. With higher speeds of sound it possible to generate higher frequency ultrasound from the same thickness of material. However, increasing the speed of sound may also increase reflection losses at boundaries (where present) within the ultrasound generation layer 18 and/or between the ultrasound generation layer 18 and the cantilever arm 14. The thickness of the ultrasound generation layer 18 will typically be less than 500 nm, optionally less than 250 nm, optionally less than 100 nm, optionally less than 50 nm.

In some embodiments, the shape of the ultrasound generation layer 18 is configured to modify the nature (e.g. frequency) of the generated ultrasound and/or enhance the conversion efficiency. For example, the ultrasound generation layer 18 may comprise one or more patterns having features at length scales smaller than the wavelength of the laser beam from the first laser unit 26. In some embodiments, the ultrasound generation layer 18 may comprise one or more loops of material, optionally closed loops, optionally concentric circles. Alternatively, the ultrasound generation layer 18 may be provided as a checker-board pattern. Detailed dimensions and/or shapes of any of the ultrasound generation layers 18 configured in this way may be derived from vibrational mode analyses of the ultrasound generation layers 18.

In an embodiment, an ultrasound detection system is provided that detects the reflected ultrasonic waves reflected back from the target structure 19. In some embodiments, the detection of the reflected ultrasonic waves comprises detecting changes in an optical reflectivity of the cantilever probe 12. In the example of FIG. 4, the ultrasound detection system comprises a second laser unit 20 and photodetector 22. The second laser unit 20 directs a laser beam onto the cantilever probe 12. In the embodiment shown, the laser beam is directed onto the ultrasound generation layer 18. The laser beam is reflected off the cantilever probe 12 (e.g. off the ultrasound generation layer 18) and detected by the photodetector 22. A data processing system 24 is provided for determining information about the target structure 19 from the detected reflected ultrasonic waves.

In an embodiment, signal acquisition is performed in a pulse-echo imaging mode that switches between a transmit mode and a receive mode. In the transmit mode, first laser unit 26 generates ultrasonic waves in the cantilever probe 12. The generated ultrasonic waves are transmitted into the target structure 19 by contact between the cantilever probe 12 and the target structure 19 (e.g. via the probe element 16 of the cantilever probe 12). In the receive mode, the second laser unit 20 probes the reflectivity of the cantilever probe 12 (e.g. by directing a laser beam onto the ultrasound generation layer 18 that is reflected and detected by the photodetector 22). This approach makes it possible to distinguish easily between light reflected to the photodetector 22 from the first laser unit 26 and light reflected to the photodetector 22 from the second laser unit 20 because the first laser unit 26 and the second laser unit 22 are operational at different times. It is also possible, however, to transmit and receive the ultrasonic waves continually and use other techniques to distinguish reflections originating from the first laser unit 26 from reflections originating from the second laser unit 20. For example, the data processing system 24 may be configured to use lock-in amplifier or similar techniques to exploit frequency and/or phase differences between the laser beams from the first laser unit 26 and the second laser unit 20. In the embodiment shown in FIG. 4, the first laser unit 26 and the second laser unit 20 are separate devices. This is advantageous because the characteristics desired for the laser beam of the first laser unit 26 (e.g. high power) are normally different to the characteristics desired for the laser beam of the second laser unit 20 (e.g. lower power). In other embodiments, however, the first laser unit 26 and the second laser unit 20 may be provided by a single unit which generates laser light that is used both for generating the ultrasonic waves and detected changes in optical reflectivity containing information about ultrasonic waves reflected back from the target structure 19.

In an embodiment, the ultrasound detection system (e.g. the second laser unit 20 and the photodetector 22) is further configured to measure a deflection of the cantilever probe 12. This may be achieved for example by monitoring a variation in the position of a reflected radiation spot on the photodetector 22.

In comparison with alternative approaches in which ultrasonic waves are generated directly within the target structure 19, for example by an actuator on a back side of the target structure 19 opposite to an atomic force microscope cantilever, the above embodiments provide several advantages.

Generating the ultrasonic waves directly in the target structure 19 can lead to errors caused by material dependent factors of the target structure 19. Furthermore, the highest acoustic frequency that is achievable is limited by the material properties of the target structure 19. Furthermore, the target structure 19 may be damaged by the process of generating the ultrasonic waves, which effectively limits the maximum power that can be used. Generating the ultrasonic waves in the cantilever arm 12 makes it possible to avoid these problems, thereby providing improved accuracy, improved spatial resolution via higher ultrasound frequencies, lower risk of damage to the target structure 19 and/or higher input powers without excessive risk of damage.

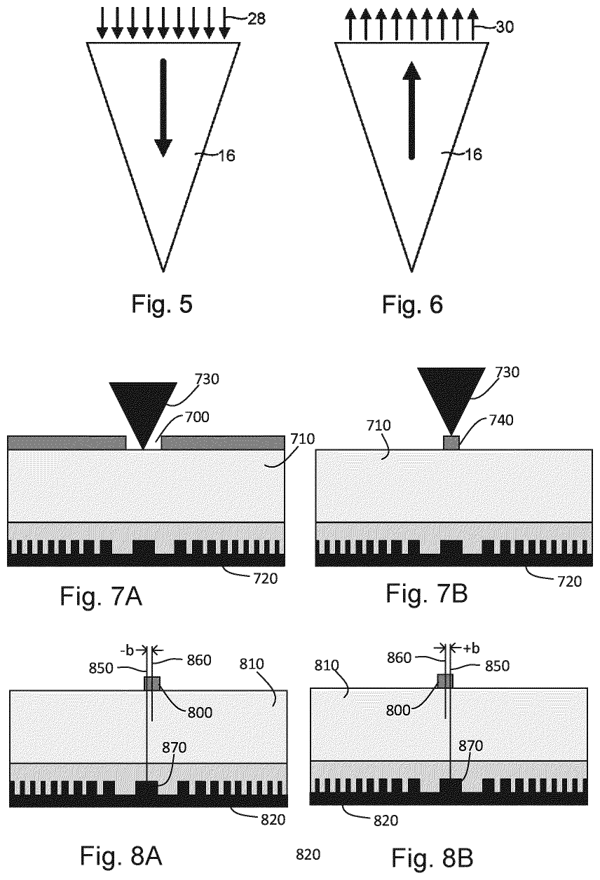

FIG. 5 depicts a probe element 16 operating in a transmit mode, with generated ultrasonic waves 28 entering the probe element 16 from the cantilever arm 14 (not shown) and propagating downwards through the probe element 16. FIG. 6 depicts the probe element 16 of FIG. 5 operating in receive mode, with reflected ultrasonic waves propagating upwards through the probe element 16 and leaving the probe element 16 (arrows 30) into the cantilever arm 14 (not shown). The probe element 16 is an example of a probe element that is tapered to have a cross-sectional area that decreases towards the target structure 19 (i.e. downwards). In this particular example, the tapering is provided over the whole vertical length of the probe element 16. The cross-sectional shape is not particularly limited but may be approximately circular for example, such that the tapered portion of the probe element 16 is conical. The tapered form acts to focus the ultrasonic waves 28 towards the target structure 19. However, the tapered form can also act to defocus reflected ultrasonic waves, making detection of the reflected ultrasonic waves more challenging. In an embodiment the probe element 16 is formed from alternating layers of materials having high and low acoustic refractive index. High acoustic refractive index material is Silicon, for example. Low acoustic refractive material may be air or PMMA, for example. The acoustic properties of the element 16 when formed from alternating layers of materials having high and low acoustic refractive index may be further controlled or improved by adjusting the pitch of the alternating layers or the filing ratio or the thickness of each layer.

Other embodiments are disclosed and described in WO2021028174A1, many of which are applicable to the concepts disclosed herein; for example providing respective separate probe elements for directing the ultrasonic waves into the target structure and receiving the reflected ultrasonic waves.

The focusing provided by the tapered form of the probe element 16 results in the propagation of ultrasonic waves in the target structure 19 resembling propagation from a point source. Three-dimensional radiation from a point source results in the intensity falling inversely proportional to r², where r is the emission radius. The intensity reaching the bottom of the target structure 19 is thus reduced by a factor of t², where t is the thickness of the target structure 19. In the absence of counter measures, the reflected intensity reaching the top of the target structure 19 will thus be reduced by a factor of t⁴ in comparison with the transmission intensity of the ultrasonic waves at the tip of the probe element 16.

To address this issue, it is proposed to configure the target being measured, so as to better direct the ultrasonic waves, which are reflected from the target, towards the probe element (e.g., probe element 16 or a separate receiving probe element where separate transmitting and receiving probe elements are provided). For example, the target may be configured to focus these reflected waves towards the probe element. This may be achieved by configuring a buried sub-structure of the target (or a plurality of sub-targets thereof) as a zone plate sub-structure (or Fresnel lens sub-structure).

The zone plate or Fresnel lens is a well-known concept which may be used to focus waves such as electromagnetic waves and/or acoustic waves. Although the separation of the structures in the zone plate sub-structure may be determined according to the equation below, it is possible to achieve wave focusing by providing a sub-structure with non-constant or varied pitch (in one, two or more directions of the substrate plane). As such, the term zone plate as described herein should be understood to mean any sub-structure with a non-constant pitch in at least one direction, the effect of the varied pitch being that reflected waves, reflected from the sub-structure, are at least partially focused towards a focus point; e.g., at a receiver or receiving probe element (which may be the same physical probe as the transmitting probe element, or a separate probe element). Note that the focus point may be interpreted herein as a point where an image as imaged by the zone plate structure is in focus, as opposed to a point at a distance from the lens defined by the focal length.

In an embodiment, the proposed target may comprise a top sub-structure or (e.g., single) reference sub-structure. The reference sub-structure may comprise, for example, a single line or feature sub-structure such as a “positive line” or positive feature, i.e., a line formed (in resist) on the layer immediately below or a “negative line” or negative feature, i.e., a line formed by a trough or trench within a layer formed (in resist) on the layer immediately below. However, other shapes or top sub-structure arrangements are possible, including a conventional grating.

The basic concept of measuring using such a target comprises firstly determining the position of the reference sub-structure or top sub-structure. This may be done using a conventional atomic force microscopy (AFM) measurement, e.g., with the probe in contact with the reference sub-structure. The zone plate sub-structure or buried sub-structure (e.g., in a buried layer) can then be measured using the passAFM technique, with the received signal being stronger than prior art methods due to the focusing effect of this zone plate sub-structure. This measurement of the zone plate sub-structure may comprise determining the strength of the received signal, where the received signal will be at a peak strength when the probe is centered on this zone plate sub-structure (i.e., when the probe is located at or nearest to a focus point of the zone plate). As such, the strength (e.g., a strength metric such as intensity) of the received signal is indicative of the position of the zone plate sub-structure with respect to the probe. This means that the position of the zone plate sub-structure with respect to the (conventionally measured) position of the reference sub-structure can be determined; this respective position of one sub-structure with respect to the other comprising the overlay.

FIG. 7 schematically illustrates in cross section such a target according to the two described examples. FIG. 7(a) is a cross-section of a stack comprising a reference sub-structure 700 in a top layer, one or more intermediate layers 710 and a zone plate sub-structure 720 in a buried layer. In this example, the reference sub-structure 700 comprises a single reference feature or line feature, more specifically a negative line as has been described (i.e., a trough or trench feature in a layer of resist).

The zone plate sub-structure 720 comprises a zone plate arrangement; i.e., a sub-structure comprising a varied pitch providing a focusing action on reflected waves from zone plate sub-structure 720 towards the probe element 730 (which maybe used for transmitting and receiving). FIG. 7(b) show the same arrangement but where the reference sub-target 740 is a positive line (i.e., a feature formed of photoresist or single line of resist).

Methods for determining overlay from such a target as disclosed will be described. These methods are largely similar to methods disclosed in the aforementioned WO2021028174A1. The information received from the signal following reflection from the target may comprise information about overlay between the reference sub-structure and the zone plate sub-structure. The overlay represents a degree of misalignment between the reference sub-structure and the zone plate sub-structure. As mentioned in the introductory part of the description, it has been difficult or impossible using existing techniques to measure overlay in targets having relatively small pitch (e.g. around 10 nm) and relatively large separation between the overlying layers (e.g. greater than 100 nm) and/or where material layers are present that are optically opaque.

In some embodiments, overlay information may be obtained by detecting the reflected ultrasonic waves at a measurement position of the cantilever arm relative to the target. In an embodiment, the measurement position is selected by using the cantilever probe in a standard atomic force microscope mode to detect the position of the reference sub-structure (e.g., positive line, negative line or other reference feature in the reference sub-structure). For example, in some embodiments, a profile of the reference sub-structure is obtained by measuring deflection of the cantilever arm caused by interaction (e.g. contact) between the probe element and the reference sub-structure and information about the zone plate sub-structure (e.g. overlay relative to the reference sub-structure or another reference) is obtained from the detected reflected ultrasonic waves.

The reflected ultrasonic waves are detected at the measurement position. At this measurement position, the probe element is aligned with a peak of the reference sub-structure. The alignment of the probe element with the reference sub-structure is determined by measuring a deflection of the cantilever arm caused by interaction (e.g. contact mode, tapping mode, non-contact mode, etc.) between the probe element and the reference sub-structure (e.g., using a standard atomic force microscopy mode).

In order to convert the measurement signal into an overlay value, deliberately applied overlay biases may be used to determine overlay. As mentioned above, an intensity/of reflected ultrasonic waves measured at any position of the probe element that is aligned with a peak in the reference sub-structure varies as a function of overlay according to a cosine function.

The overlay is typically a relatively small value, which means that the variation of intensity with overlay is non-linear and relatively weak (i.e., around the peak of a cosine (or sine) function). In an embodiment, the variation of signal magnitude (e.g., intensity) with overlay is improved by using a target that comprises multiple sub-targets, wherein one or more of the sub-targets comprises an overlay bias deliberately applied to them.

FIG. 8 illustrates an embodiment where the target comprises a first sub-target (FIG. 8(a)) and a second sub-target (FIG. 8(b)). In this context, an overlay bias-b, +b may comprise a deliberate displacement of a reference point 860 (e.g., the center) of the reference sub-structure 800 with respect to a reference point 850 (e.g., the center) of a center feature 870 of the zone plate sub-structure 820. The first and second sub-targets may be positioned in close proximity to each other on a substrate, such as directly adjacent to each other. The overlay bias of the first sub-target is different to the overlay bias of the second sub-target. In the specific example shown these biases are equal in magnitude and opposite in direction, although this is not a requirement. This difference shifts the cosine variation mentioned above and improves variation of intensity an overlay. For example, by careful choice of the bias magnitude, the cosine dependence of the measured signal magnitude (e.g., intensity) with overlay may be converted into a sine dependence, thereby providing a linear and relatively steep variation of intensity with overlay.

In such an embodiment, the intensity difference (or measurement signal magnitude difference) ΔI=KOV, where OV is the overlay and K a proportionality constant which can be pre-derived using calibration measurements. For example, the value of the constant K could be determined using a set of calibration targets with a set of programmed bias values (e.g., ranging from a positive bias value to a negative bias value). Once K is learned by calibration, only two sub-targets (e.g. with a first offset +b and second offset −b) are needed to determine the overlay. Thus, overlay can be determined from a difference between: an intensity of a detected reflected ultrasonic wave from the zone plate sub-target of the first sub-target when the probe element is aligned with the reference sub-structure of the first sub-target; and an intensity of a detected reflected ultrasonic wave from the zone plate sub-target of the second sub-target when the probe element is aligned with the reference sub-structure of the second sub-target.

In some embodiments, the need for calibration measurements may be reduced or removed by using further sub-targets (e.g., in a similar manner as described in WO2021028174A1). In one class of such an embodiment, four such sub-targets may be used, e.g., a first sub-target, second sub-target, third sub-target, and fourth sub-target. The first sub-target, second sub-target, third sub-target and fourth sub-target may each comprise two sub-structures with a deliberately applied overlay bias between the two sub-structures as has been described, with the overlay biases of the first sub-target, second sub-target, third sub-target and fourth sub-target being all different. The overlay bias of the first sub-target may be −a+b. The overlay bias of the second sub-target may be +a+b. The overlay bias of the third sub-target may be −a−b. The overlay bias of the fourth sub-target may be +a−b, where a and b are constants. The overlay can be determined from a combination of measurement signal magnitudes or intensities from each of these sub-targets; e.g., an intensity of a detected reflected ultrasonic wave from the each respective sub target when the probe element is aligned with the reference sub-structure of that sub-target. More specifically, it can be appreciated that:

I₁−I₂=K(OV+b)

I₃−I₄=K(OV−b)

and therefore overlay OV can be determined as:

$$OV = \frac{{I}_{1} - {I}_{2} + {I}_{3} - {I}_{4}}{{I}_{1} - {I}_{2} - {I}_{3} + {I}_{4}}$$

where I₁, I₂, I₃, I₄ are the measured intensities of the first sub-target, second sub-target, third sub-target and fourth sub-target respectively.

The zone plate sub-structure may comprise any suitable form, including a linear or unidimensional zone plate structure, a two-dimensional (e.g., rectangular) zone plate structure or radial zone plate structure. The spacing of the elements of the zone plate structure may comprise any (non-constant pitch) spacing which provides a focusing effect.

A function of the sub-surface structure 720 is not only to focus a wave on the tip of the AFM cantilever generally, but to do so efficiently for waves that are generated by a point/local source on the surface of the target. Therefore, if the focal length of the Fresnel lens is f, then

$$\frac{1}{f} = \frac{1}{{s}_{0}} + \frac{1}{{s}_{i}} ,$$

where s₀=sᵢ, and therefore the distance d between the cantilever tip and sub-surface structure may be approximately

$${s}_{0} = {s}_{i} = d = \frac{F}{2} ,$$

where r is the focal distance of the zone plate sub-structure.

Focal distance F of the zone plate sub-structure is related to acoustic wavelength λ, the distance d of source to the zone plate and the pitches of the structures in the lens. The mathematical relation between these may be expressed in the formula:

$$d + F + \frac{n λ}{2} = \sqrt{{r}_{n}^{2} + {d}^{2}} + \sqrt{{r}_{n}^{2} + {F}^{2}}$$

where rₙ is the zone plate sub-structure locations (distance from a center sub-structure) or radii where n is an integer (e.g., such that the location of the first feature from the center is r₁, next feature r² etc.). Based on this, in an embodiment, and assuming

$$d = \frac{F}{2}$$

as the aim is to focus the waves back to the source location (tip of the cantilever) in reflection mode, the zone plate sub-structure feature locations or radii within the proposed target may be determined according to the above equation.

Overall, the zone plate dimensions comprise a compromise between the focal depth, minimum printable CD (e.g., 50 nm, although this may be smaller using patterning techniques) and total target size (which may be fixed). By way of specific example, a radial zone plate having an approximately 5 μm radius and 50 nm minimum CD can achieve focal depth at 4 μm. For thick stacks such as 3DNAND, the focus depth may be around 10 μm, which results in a minimum CD of approximately 125 nm.

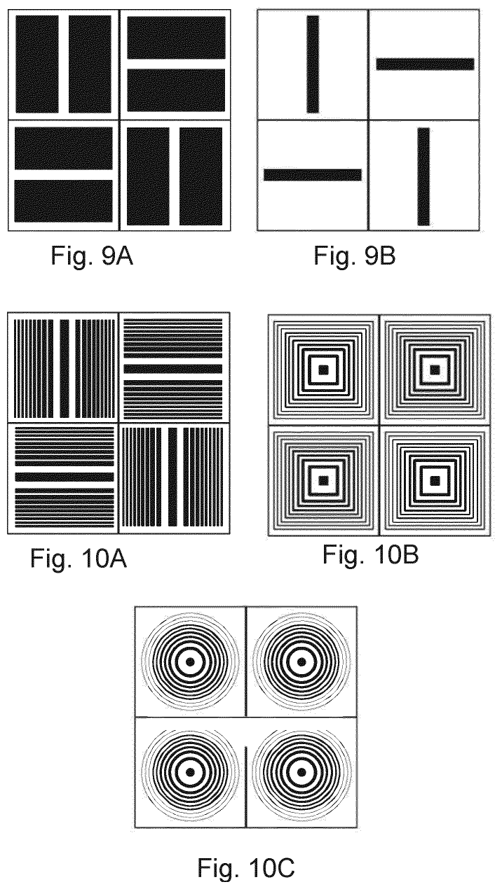

FIG. 9 is a schematic illustration from above of two alternative reference sub-structure layers for a target arrangement comprising two biased sub-targets +x, −x in a first direction and two biased sub-targets −y, +y in a second direction. In this embodiment, the reference sub-structures are all of the negative line type. FIG. 9(b) shows a reference sub-structure layer for the same target arrangement, i.e., comprising two biased sub-targets 920 in a first direction and two biased sub-targets 930 in a second direction, but where the reference sub-structures are all of the positive line type. In an embodiment using four biases as has been described, each of these target arrangements may comprise four sub-targets per direction.

FIG. 10 shows alternative zone-plate sub-structure layers for a target arrangement comprising two biased sub-targets +x, −x in a first direction and two biased sub-targets −y, +y in a second direction. FIG. 10(a) shows linear zone-plate sub-structures, FIG. 10(b) shows rectangular zone-plate sub-structures and FIG. 10(c) shows circular zone-plate sub-structures. In an embodiment using four biases as has been described, each of these target arrangements may comprise four sub-targets per direction.

It can be appreciated that an overlay target arrangement may comprise any combination of a reference sub-structure layer depicted in FIG. 9 (or other reference sub-structure layer) and a zone-plate sub-structure layer as depicted in FIG. 10 (or other zone-plate sub-structure layer).

Further embodiments according to the present invention are described in below numbered clauses:
1. A substrate comprising at least one target, said target comprising: a reference sub-structure in a top layer; and a buried sub-structure in a buried layer below the top layer, wherein said buried sub-structure comprises a non-constant pitch in at least one direction, the effect of the non-constant pitch being that reflected waves, reflected from the sub-structure as a result of a measurement of said target, are at least partially focused towards a focus point.
2. A substrate according to clause 1, wherein said reference sub-structure comprises a single reference feature.
3. A substrate according to clause 2, wherein said single reference feature comprises a single line feature.
4. A substrate according to clause 2 or 3, wherein said single reference feature comprises a feature formed of photoresist.
5. A substrate according to clause 2 or 3, wherein said single reference feature comprises a trough feature formed within a photoresist layer.
6. A substrate according to any preceding clause, wherein said buried sub-structure comprises a zone plate sub-structure.
7. A substrate according to clause 6, wherein said zone plate sub-structure comprises a linear zone plate sub-structure.
8. A substrate according to clause 6, wherein said zone plate sub-structure comprises a rectangular zone plate sub-structure.
9 A substrate according to clause 6, wherein said zone plate sub-structure comprises a circular zone plate sub-structure.
10. A substrate according to any preceding clause, wherein said target comprises a plurality of sub-targets, each sub-target comprising a respective said reference sub-structure and a respective said buried sub-structure; where said plurality of sub-targets comprise at least a first set of sub-targets comprising at least a sub-target comprising a first bias and a sub-target comprising a second bias, each said bias comprising a position bias between said reference sub-structure and buried sub-structure.
11. A substrate according to clause 10, wherein said first set of sub-targets comprises at least a sub-target comprising a first bias, a sub-target comprising a second bias, a sub-target comprising a third bias and a sub-target comprising a fourth bias.
12. A substrate according to clause 11, wherein said first bias is −a+b, said second bias is +a+b, said third bias is −a−b and said fourth bias is +a−b, where a and b are constants.
13. A substrate according to clause 10, 11 or 12, wherein said plurality of sub-targets comprises said first set of sub-targets aligned with a first direction of a substrate plane and a corresponding second set of sub-targets targets aligned with a second direction of the substrate plane, said first direction being perpendicular to said second direction.
14. A method of measuring a parameter of interest value by measuring a target, the target comprising a reference sub-structure in a top layer; and a buried sub-structure in a buried layer below the top layer, wherein said buried sub-structure comprises a non-constant pitch in at least one direction, the effect of the non-constant pitch being that reflected waves, reflected from the sub-structure as a result of a measurement of said target, are at least partially focused towards a focus point; the method comprising:
a) determining a position of the reference structure via an atomic force microscopy method;
b) generating acoustic waves at the position of the reference structure determined at step a) and directing said acoustic waves towards said buried sub-structure;
c) measuring a strength metric value of a reflected wave at the positon of the reference structure determined at step a), having reflected from said buried sub-structure as a result of step b); and
d) determining a parameter of interest value from the strength metric value.
15. A method according to clause 14, wherein said strength metric value of said reflected wave comprises an intensity value of said reflected wave.
16. A method according to clause 14 or 15, wherein said parameter of interest value is an overlay value.
17. A method according to any of clauses 14 to 16, wherein said target comprises a plurality of sub-targets, each sub-target comprising a respective said reference sub-structure and a respective said buried sub-structure; where said plurality of sub-targets comprise at least a first set of sub-targets comprising at least a sub-target comprising a first bias and a sub-target comprising a second bias, each said bias comprising a position bias between said reference sub-structure and buried sub-structure; and said method further comprises:
performing steps a) to c) for each sub-target to obtain respective strength metric values for each sub-target; and
determining one or more parameter of interest values from said strength metric values.
18. A method according to clause 17, wherein said method comprises:
obtaining a calibrated proportionality constant relating said parameter of interest to said strength metric; and
determining said one or more parameter of interest values from said strength metric values and said calibrated proportionality constant.
19. A method according to clause 17, wherein said first set of sub-targets comprises at least a sub-target comprising a first bias, a sub-target comprising a second bias, a sub-target comprising a third bias and a sub-target comprising a fourth bias; and said determining one or more parameter of interest values from said strength metric values comprises determining the one or more parameter of interest values without a calibrated proportionality constant.
20. A method according to clause 19, wherein said first bias is −a+b, said second bias is +a+b, said third bias is −a−b and said fourth bias is +a−b, where a and b are constants.
21. A method according to clause 18, 19 or 20, wherein said plurality of sub-targets comprises said first set of sub-targets aligned with a first direction of a method plane and a corresponding second set of sub-targets targets aligned with a second direction of the method plane, said first direction being perpendicular to said second direction; and said method comprises determining a first parameter of interest value from the first set of sub-targets and a second parameter of interest value from the second set of sub-targets.
22. A method according to any of clauses 14 to 21, wherein said reference sub-structure comprises a single reference feature.
23. A method according to clause 22, wherein said single reference feature comprises a single line feature.
24. A method according to clause 22 or 23, wherein said single reference feature comprises a feature formed of photoresist.
25. A method according to clause 22 or 23, wherein said single reference feature comprises a trough feature formed within a photoresist layer.
26. A method according to any of clauses 14 to 25, wherein said buried sub-structure comprises a zone plate sub-structure.
27. A method according to clause 26, wherein said zone plate sub-structure comprises a linear zone plate sub-structure.
28. A method according to clause 26, wherein said zone plate sub-structure comprises a rectangular zone plate sub-structure.
29. A method according to clause 26, wherein said zone plate sub-structure comprises a circular zone plate sub-structure.
30. A method according to any of clauses 14 to 29, wherein said measuring a strength metric value of a reflected wave at step c) comprises measuring said strength metric value for the reflected wave at said focus point.
31. A method according to any of clauses 14 to 30, wherein said generating acoustic waves at step b) comprises generating the acoustic waves at said focus point.
32. A metrology device operable to perform the method of any of clauses 17 to 31.
33. A metrology device according to clause 32, comprising a photoacoustic sub-surface atomic force microscopy device.
34. A set of reticles for manufacturing the substrate of any of clauses 1 to 16, said set of reticles comprising a first reticle for forming said buried layer and a second reticle for forming said top layer, so as to form said target on said substrate.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of an inspection or metrology apparatus, embodiments of the invention may be used in other apparatus. Embodiments of the invention may form part of a mask inspection apparatus, a lithographic apparatus, or any apparatus that measures or processes an object such as a wafer (or other substrate) or mask (or other patterning device). The term “metrology apparatus” may also refer to an inspection apparatus or an inspection system. E.g. the inspection apparatus that comprises an embodiment of the invention may be used to detect defects of a substrate or defects of structures on a substrate. In such an embodiment, a characteristic of interest of the structure on the substrate may relate to defects in the structure, the absence of a specific part of the structure, or the presence of an unwanted structure on the substrate.

Although specific reference is made to “metrology apparatus/tool/system” or “inspection apparatus/tool/system”, these terms may refer to the same or similar types of tools, apparatuses or systems. E.g. the inspection or metrology apparatus that comprises an embodiment of the invention may be used to determine characteristics of structures on a substrate or on a wafer. E.g. the inspection apparatus or metrology apparatus that comprises an embodiment of the invention may be used to detect defects of a substrate or defects of structures on a substrate or on a wafer. In such an embodiment, a characteristic of interest of the structure on the substrate may relate to defects in the structure, the absence of a specific part of the structure, or the presence of an unwanted structure on the substrate or on the wafer.

Although specific reference may have been made above to the use of embodiments of the invention in the context of optical lithography, it will be appreciated that the invention, where the context allows, is not limited to optical lithography and may be used in other applications, for example imprint lithography.

While the targets or target structures (more generally structures on a substrate) described above are metrology target structures specifically designed and formed for the purposes of measurement, in other embodiments, properties of interest may be measured on one or more structures which are functional parts of devices formed on the substrate. Many devices have regular, grating-like structures. The terms structure, target grating and target structure as used herein do not require that the structure has been provided specifically for the measurement being performed.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1.-15. (canceled)

16. A substrate comprising:
at least one target comprising:
a reference sub-structure in a top layer; and
a buried sub-structure in a buried layer below the top layer,
wherein the buried sub-structure comprises a non-constant pitch in at least one direction such that waves reflected from the buried sub-structure are at least partially focused towards a focus point to thereby result in a measurement of the at least one target.

17. The substrate of claim 16, wherein the buried sub-structure comprises a zone plate sub-structure.

18. The substrate of claim 17, wherein the zone plate sub-structure comprises a linear zone plate sub-structure.

19. The substrate of claim 17, wherein the zone plate sub-structure comprises a rectangular zone plate sub-structure.

20. The substrate of claim 17, wherein the zone plate sub-structure comprises a circular zone plate sub-structure.

21. The substrate of claim 16, wherein the at least one target comprises a plurality of sub-targets, each sub-target comprising a respective reference sub-structure and a respective buried sub-structure, wherein the plurality of sub-targets comprise at least a first set of sub-targets comprising at least a sub-target comprising a first bias and a sub-target comprising a second bias, wherein each of the first and second bias comprises a position bias between a given reference sub-structure and a corresponding buried sub-structure.

22. A method of measuring a parameter of interest value by measuring a target comprising a reference sub-structure in a top layer and a buried sub-structure in a buried layer below the top layer, wherein the buried sub-structure comprises a non-constant pitch in at least one direction, and an effect of the non-constant pitch being that reflected waves, reflected from the sub-structure as a result of a measurement of the target, are at least partially focused towards a focus point, the method comprising:
a) determining a position of the reference structure using an atomic force microscopy;
b) generating acoustic waves at the positon of the reference structure determined at step a) and directing the acoustic waves towards the buried sub-structure;
c) measuring a strength metric value of a reflected wave at the determined positon of the reference structure determined at step a), having reflected from the buried sub-structure as a result of step b); and
d) determining a parameter of interest value from the strength metric value.

23. The method of claim 22, wherein the strength metric value of the reflected wave comprises an intensity value of the reflected wave.

24. The method of claim 22, wherein the parameter of interest value is an overlay value.

25. A method of claim 22, wherein the target comprises a plurality of sub-targets, each sub-target comprising a respective reference sub-structure and a respective buried sub-structure, wherein the plurality of sub-targets comprise at least a first set of sub-targets comprising at least a sub-target comprising a first bias and a sub-target comprising a second bias, and wherein each of the first and second bias comprises a position bias between a given reference sub-structure and a corresponding buried sub-structure, and the method further comprises:
performing steps a) to c) for each sub-target to obtain respective strength metric values for each sub-target; and
determining one or more parameter of interest values from the strength metric values.

26. The method of claim 22, wherein the measuring a strength metric value of a reflected wave at step c) comprises measuring the strength metric value for the reflected wave at the focus point.

27. The method of claim 22, wherein the generating acoustic waves at step b) comprises generating the acoustic waves at the focus point.

28. A metrology device operable to perform the method of claim 22.

29. The metrology device of claim 28, wherein the metrology device comprises a photoacoustic sub-surface atomic force microscopy device.

30. A set of reticles for manufacturing the substrate of claim 16, the set of reticles comprising a first reticle for forming the buried layer and a second reticle for forming the top layer, so as to form the target on the substrate.
